(19) United States
(12) Patent Application Publication
(10) Pub. No.: US 2024/0324291 A1
(43) Pub. Date: Sep. 26, 2024

(54) DISPLAY DEVICE

(71) Applicant: Samsung Display Co., Ltd., Yongin-si (KR)

(72) Inventors: Ran Kim, Yongin-si (KR); Kihyun Kim, Yongin-si (KR)

(73) Assignee: Samsung Display Co., Ltd., Yongin-si (KR)

(21) Appl. No.: 18/613,430

(22) Filed: Mar. 22, 2024

(30) Foreign Application Priority Data
Mar. 24, 2023 (KR) 10-2023-0039043
Jul. 11, 2023 (KR) 10-2023-0090027

(51) Int. Cl. H10K 59/121; H01L 29/786; H10K 59/131

(52) U.S. Cl. CPC H10K 59/1213; H01L 29/78693; H10K 59/1216; H10K 59/131

(57) ABSTRACT

A display device includes a transistor including a semiconductor layer and a gate electrode overlapping a channel area of the semiconductor layer and a storage capacitor electrically connected to the transistor, the storage capacitor including a first capacitor electrode disposed below the semiconductor layer, a second capacitor electrode disposed on the first capacitor electrode, and a third capacitor electrode disposed on the second capacitor electrode, the second capacitor electrode includes a lower layer, the lower layer and the semiconductor layer being disposed on a same layer, an intermediate layer disposed on the lower layer, and an upper layer disposed on the intermediate layer, and the upper layer of the second capacitor electrode includes an amorphous conductive oxide.

### CROSS-REFERENCE TO RELATED APPLICATIONS

This application claims priority to and benefits of Korean Patent Application Nos. 10-2023-0039043 and 10-2023-0090027 under 35 U.S.C. § 119, filed on Mar. 24, 2023, and Jul. 11, 2023, respectively, in the Korean Intellectual Property Office, the entire contents of which are incorporated herein by reference.

### BACKGROUND

### 1. Technical Field

One or more embodiments relate to a display device.

### 2. Description of the Related Art

Display devices display data in a visual manner. Display devices are used as display units of small-sized products such as mobile phones and also as display units of large-sized products such as televisions.

Display devices may include liquid-crystal display devices using light from backlight units without emitting light or light-emitting display devices including display elements that emit light. The display elements may include emission layers. Such display devices may be formed by alternately stacking conductive layers and insulating layers.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display device with improved reliability.

However, the above-noted technical goal is only an example and the technical goals of one or more embodiments are not limited thereto.

Additional aspects will be set forth in part in the description which follows and, in part, will be apparent from the description, or may be learned by practice of the embodiments of the disclosure.

According to one or more embodiments, a display device may include a transistor including a semiconductor layer and a gate electrode overlapping a channel area of the semiconductor layer and a storage capacitor electrically connected to the transistor and including a first capacitor electrode disposed below the semiconductor layer; a second capacitor electrode disposed on the first capacitor electrode; and a third capacitor electrode disposed on the second capacitor electrode, wherein the second capacitor electrode may include a lower layer, the lower layer and the semiconductor layer being disposed on a same layer; an intermediate layer disposed on the lower layer; and an upper layer disposed on the intermediate layer, and the upper layer of the second capacitor electrode may include an amorphous conductive oxide.

In an embodiment, the display device may further include a buffer layer disposed between the first capacitor electrode and the second capacitor electrode and an inorganic insulating layer including a first insulating pattern disposed between the semiconductor layer and the gate electrode and a second insulating pattern disposed between the second capacitor electrode and the third capacitor electrode. The first insulating pattern may be disposed directly on the semiconductor layer, and the second insulating pattern may be disposed directly on the upper layer of the second capacitor electrode.

In an embodiment, a thickness of the intermediate layer may be less than a thickness of the lower layer and a thickness of the upper layer of the second capacitor electrode.

In an embodiment, the thickness of the lower layer may be less than the thickness of the upper layer of the second capacitor electrode.

In an embodiment, the thickness of the intermediate layer of the second capacitor electrode may be about 5 Å or more but not more than about 50 Å.

In an embodiment, the lower layer and the intermediate layer may each include an amorphous conductive oxide.

In an embodiment, the upper layer may include amorphous zinc indium oxide (ZIO), and the ZIO may include zinc (Zn) of about 12 at % or more but not more than about 16 at %, indium (In) of about 13 at % or more but not more than about 23 at %, and oxygen (O) of about 58 at % or more but not more than about 65 at %.

In an embodiment, the intermediate layer may include In of about 10 at % or more but not more than about 30 at %.

In an embodiment, the intermediate layer may further include Ga of more than about 0 at % but not more than about 20 at %.

In an embodiment, the lower layer may include amorphous indium gallium zinc oxide (IGZO).

In an embodiment, the intermediate layer may be in an entire area between the lower layer and the upper layer of the second capacitor electrode.

In an embodiment, the intermediate layer may be in an area between the lower layer and the upper layer of the second capacitor electrode.

In an embodiment, the display device may further include a wiring, the wiring and the first capacitor electrode being disposed on a same layer and a conductive layer disposed on the semiconductor layer, and the conductive layer may be electrically connected to the wiring.

In an embodiment, the conductive layer may include a first conductive layer, the first conductive layer and the intermediate layer of the second capacitor electrode being disposed on a same layer and a second conductive layer disposed on the first conductive layer, the second conductive layer and the upper layer of the second capacitor electrode being disposed on a same layer.

A display device may include a transistor including a semiconductor layer and a gate electrode overlapping a channel area of the semiconductor layer; and a storage capacitor electrically connected to the transistor and including a first capacitor electrode disposed below the semiconductor layer; a second capacitor electrode disposed on the first capacitor electrode; and a third capacitor electrode disposed on the second capacitor electrode, wherein the second capacitor electrode may include a lower layer, the lower layer and the semiconductor layer being disposed on a same layer; and an upper layer disposed on the lower layer, and each of the lower layer and the upper layer of the second capacitor electrode may include an amorphous conductive oxide.

In an embodiment, the upper layer may include amorphous zinc indium oxide (ZIO).

In an embodiment, the ZIO may include Zn of about 12 at % or more but not more than about 16 at %, In of about 13 at % or more but not more than about 23 at %, and O of about 58 at % or more but not more than about 65 at %.

In an embodiment, the second capacitor electrode may further include an intermediate layer disposed between the lower layer and the upper layer, and the intermediate layer may include an amorphous conductive oxide including atoms included in the lower layer and atoms included in the upper layer of the second capacitor electrode.

In an embodiment, the thickness of the intermediate layer may be less than a thickness of the upper layer and a thickness of the lower layer of the second capacitor electrode.

In an embodiment, the display device may further include a wiring, the wiring and the first capacitor electrode being disposed on a same layer and a conductive layer disposed on the semiconductor layer, wherein the conductive layer may be electrically connected to the wiring and the conductive layer and the upper layer of the second capacitor electrode may be disposed on a same layer.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic perspective view schematically illustrating a display device according to an embodiment;

FIG. 2A is a schematic cross-sectional view of the display device shown in FIG. 1, taken along line A-A′;

FIG. 2B is a schematic diagram illustrating a first color-converter, a second color-converter, and a transmitter shown in FIG. 2A;

FIG. 3 is a schematic top-plan view schematically illustrating an emission panel according to an embodiment;

FIG. 4 is a schematic diagram of an equivalent circuit of a pixel circuit and a display element included in an emission panel according to an embodiment;

FIG. 5 is a schematic cross-sectional view schematically illustrating an emission panel according to an embodiment, taken along line B-B′ of the emission panel shown in FIG. 3;

FIG. 6 is an enlarged view illustrating an enlarged image of a second capacitor electrode of an area ‘E’ shown in FIG. 5, according to an embodiment;

FIG. 7 is an enlarged schematic view illustrating an enlarged image of the second capacitor electrode of the area ‘E’ shown in FIG. 5, according to an embodiment; and

FIG. 8 is an enlarged schematic view illustrating an enlarged image of the second capacitor electrode of the area ‘E’ shown in FIG. 5, according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Throughout the disclosure, the expression “at least one of a, b or c” indicates only a, only b, only c, both a and b, both a and c, both b and c, all of a, b, and c, or variations thereof.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

It will be further understood that the terms “comprise,” “comprising,” “include,” “including,” “have,” “having,” and the like, used herein, specify the presence of stated features and/or elements, but do not preclude the presence or addition of one or more other features and/or elements.

In the following embodiments, when a portion such as a film, an area, or a component is on or above another portion, the portion may be directly on the other portion, or other films, areas, or components may be located or disposed therebetween.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

In the drawings, the sizes of elements may be exaggerated or reduced for convenience For example, since the size and thickness of each element is arbitrarily shown in the drawings for convenience of description, the disclosure is not necessarily limited to those illustrated.

In the following embodiments, an x-axis, a y-axis, and a z-axis are not limited to three axes on an orthogonal coordinate system, and may be broadly interpreted. For example, the x-axis, y-axis, and z-axis may be orthogonal to one another, but may also refer to different directions that are not orthogonal to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

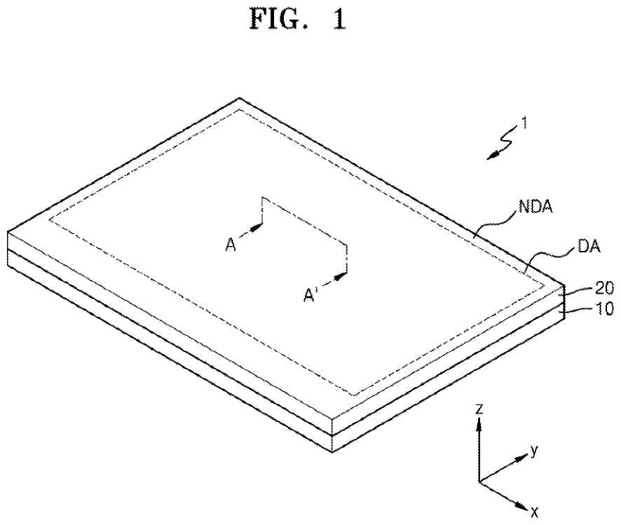

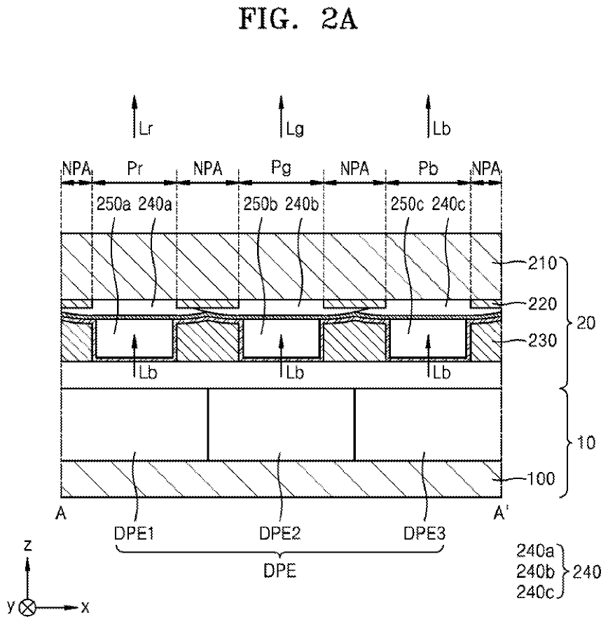

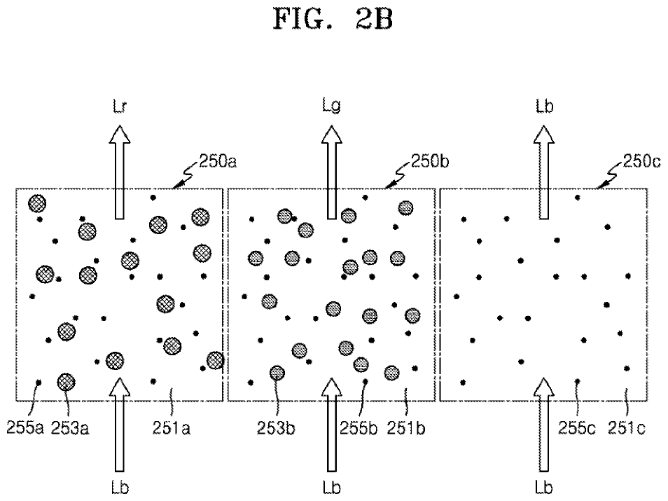

FIG. 1 is a schematic perspective view schematically illustrating a display device 1 according to an embodiment. FIG. 2A is a schematic cross-sectional view of the display device 1 shown in FIG. 1, taken along line A-A′. FIG. 2B is a schematic diagram illustrating a first color-converter, a second color-converter, and a transmitter shown in FIG. 2A.

Referring to FIG. 1, the display device 1 may display images. The display device 1 may include a display area DA and a non-display area NDA. The display device 1 may provide images through subpixels arranged or disposed in the display area DA. Each of the subpixels of the display device 1 may include an area from which light having a given color may be emitted, and the display device 1 may display images using the light emitted from the subpixels. For example, a subpixel may emit red, green, or blue light. As another example, a subpixel may emit red, green, blue, or white light.

The non-display area NDA may at least partially surround the display area DA. In an embodiment, the non-display area NDA may entirely surround the display area DA. The non-display area NDA may include an area that does not provide images.

As shown in FIG. 1, the display area DA may have a polygon shape including a square. For example, the display area DA may have a rectangular shape in which a horizontal length is greater than a vertical length, a rectangular shape in which a horizontal length is less than a vertical length, or a square shape. For example, the display area DA may have various shapes such as an oval or a circle. In an embodiment, the display device 1 may include an emission panel 10 and a color panel 20 stacked each other in a thickness direction (for example, a z direction).

Referring to FIGS. 2A and 2B, the emission panel 10 may include display elements DPE disposed on a substrate 100. In an embodiment, the display elements DPE may include a first display element DPE1, a second display element DPE2, and a third display element DPE3. Although not shown in FIG. 2A, the first display element DPE1, the second display element DPE2, and the third display element DPE3 may each be electrically connected to a pixel circuit and driven by the pixel circuit.

The first display element DPE1, the second display element DPE2, and the third display element DPE3 may each emit light. In an embodiment, the first display element DPE1, the second display element DPE2, and the third display element DPE3 may emit a same kind of light. For example, the first display element DPE1, the second display element DPE2, and the third display element DPE3 may emit any one of red light Lr, green light Lg, and blue light Lb. As another example, the first display element DPE1, the second display element DPE2, and the third display element DPE3 may emit any one of red light Lr, green light Lg, blue light Lb, and white light. According to an embodiment, any one of the first display element DPE1, the second display element DPE2, the third display element DPE3 and another one of the first display element DPE1, the second display element DPE2, and the third display element DPE3 may emit different kinds of light. For example, the first display element DPE1 may emit the red light Lr, the second display element DPE2 may emit the green light Lg, and the third display element DPE3 may emit the blue light Lb. As another example, the first display element DPE1 may emit the red light Lr, the second display element DPE2 may emit the green light Lg, the third display element DPE3 may emit the blue light Lb, and a fourth display element may emit white light. Hereinafter, a case in which the first display element DPE1, the second display element DPE2, and the third display element DPE3 all emit the blue light Lb will be described in detail.

The color panel 20 may be disposed on the emission panel 10. The color panel 20 may modify a wavelength of light emitted from the emission panel 10. According to an embodiment, the color panel 20 may be disposed on the display elements DPE. The color panel 20 may modify a wavelength of light emitted from the display elements DPE. According to an embodiment, the blue light Lb emitted from the first display element DPE1, the second display element DPE2, and the third display element DPE3 may be modified into the red light Lr, the green light Lg, and the blue light Lb or be transmitted while passing through the color panel 20. An area from which the red light Lr is emitted may correspond to a red subpixel Pr. An area from which the green light Lg is emitted may correspond to a green subpixel Pg. An area through which the blue light Lb is transmitted may correspond to a blue subpixel Pb.

The color panel 20 may include an upper substrate 210, a first light-shielding layer 220, a second light-shielding layer 230, a color filter 240, a first color-converter 250a, a second color-converter 250b, and a transmitter 250c. The first light-shielding layer 220 may include holes formed as portions corresponding to the red subpixel Pr, the green subpixel Pg, and the blue subpixel Pb are removed. The first light-shielding layer 220 may include a material portion overlapping a non-pixel area NPA, and the material portion may include various materials capable of absorbing light.

The second light-shielding layer 230 may be disposed on the first light-shielding layer 220. The second light-shielding layer 230 may include a material portion overlapping the non-pixel area NPA, and the material portion may include various materials capable of absorbing light. The second light-shielding layer 230 may include a material identical to or different from a material of the first light-shielding layer 220. According to an embodiment, the first light-shielding layer 220 and/or the second light-shielding layer 230 may include an opaque inorganic insulating material such as chromium oxide or molybdenum oxide, or may include an opaque organic insulating material such as a black resin.

The color filter 240 may include a first color filter 240a, a second color filter 240b, and a third color filter 240c. The first color filter 240a may include a pigment or a dye having a first color (for example, red). The second color filter 240b may include a pigment or a dye having a second color (for example, green). The third color filter 240c may include a pigment or a dye having a third color (for example, blue).

The first color-converter 250a, the second color-converter 250b, and the transmitter 250c may be disposed between the color filter 240 and the display element DPE.

The first color-converter 250a may overlap the first color filter 240a and may convert the blue light Lb being incident to the red light Lr. The first color-converter 250a may include a first photosensitive polymer 251a, first quantum dots 253a, and first scattering particles 255a. The first quantum dots 253a and the first scattering particles 255a may be distributed in the first photosensitive polymer 251a.

The first quantum dots 253a may be excited by the blue light Lb to emit the red light Lr having a wavelength longer than a wavelength of the blue light Lb. The first photosensitive polymer 251a may include an organic material having light-transmittance. The first scattering particles 255a may scatter the blue light Lb that has not been absorbed into the first quantum dots 253a, such that a greater number of the first quantum dots 253a are excited, to thereby improve color conversion efficiency. The first scattering particles 255a may include, for example, titanium oxide (TiO₂), metal particles, or the like within the spirit and the scope of the disclosure. The first quantum dots 253a may be selected from among Group II-VI compounds, Group III-V compounds, Group IV-VI compounds, Group IV elements, Group IV compounds, and combinations thereof.

The second color-converter 250b may overlap the second color filter 240b and may convert the blue light Lb being incident to the green light Lg. The second color-converter 250b may include a second photosensitive polymer 251b, second quantum dots 253b, and second scattering particles 255b. The second quantum dots 253b and the second scattering particles 255b may be scattered in the second photosensitive polymer 251b.

The second quantum dots 253b may be excited by the blue light Lb to emit the green light Lg having a wavelength greater than the wavelength of the blue light Lb. The second photosensitive polymer 251b may include an organic material having light-transmittance. The second scattering particles 255b may scatter the blue light Lb that has not been absorbed into the second quantum dots 253b, such that a greater number of the second quantum dots 253b are excited, to thereby improve color conversion efficiency. The second scattering particles 255b may include, for example, TiO₂, metal particles, or the like within the spirit and the scope of the disclosure. The second quantum dots 253b may be selected from among the Group II-VI compounds, the Group III-V compounds, the group IV-VI compounds, the Group IV elements, the Group IV compounds, and combinations thereof.

By way of example, in the specification, quantum dots (for example, the first quantum dots 253a and the second quantum dots 253b) indicate crystals of a semiconductor compound, and may include an arbitrary material emitting light of various emission wavelengths according to sizes of crystals. A diameter of the quantum dots may be, for example, in a range of about 1 nm to about 10 nm.

The quantum dot may be synthesized through a wet chemical process, a metal organic chemical vapor deposition process, molecular beam epitaxy process, or other similar processes. The wet chemical process is a method of growing quantum-dot particle crystals after mixing an organic solution and a precursor material. During growth of the crystals, an organic solvent naturally functions as a distributor coordinated on a surface of the crystal of the quantum-dot and adjusts the growth of the crystal, and therefore, the wet chemical process is easier to perform than MOCVD or MBE, and the growth of quantum-dot particles may be controlled through a low-cost process.

The quantum dots may include a Group II-VI semiconductor compound, a Group III-V semiconductor compound, a Group III-VI semiconductor compound, a Group I-III-VI semiconductor compound, a group IV-VI semiconductor compound, a Group IV element or compound, or an arbitrary combination thereof.

Examples of the Group II-VI semiconductor compound may include a two-element compound such as CdS, CdSe, CdTe, ZnS, ZnSe, ZnTe, ZnO, HgS, HgSe, HgTe, MgSe, MgS, or the like, a three-element compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or the like, a four-element compound such as CdZnSeS, CdZnSeTe, CdZnSTe, CdHgSeS, CdHgSeTe, CdHgSTe, HgZnSeS, HgZnSeTe, HgZnSTe, or the like, or an arbitrary combination thereof.

Examples of the Group III-V semiconductor compound may include a two-element compound such as GaN, GaP, GaAs, GaSb, AlN, AIP, AlAs, AlSb, InN, InP, InAs, InSb, or the like, a three-element compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, or the like, a four-element compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or the like, or an arbitrary combination thereof. The Group III-V semiconductor compound may further include a Group II element. Examples of the Group III-V semiconductor compound further including the Group II element may include InZnP, InGaZnP, InAlZnP, or the like within the spirit and the scope of the disclosure.

Examples of the Group III-VI semiconductor compound may include a two-element compound such as GaS, GaSe, GazSe₃, GaTe, InS, In₂S₃, InSe, In₂Se₃, InTe, or the like, a three-element compound such as AgInS, AgInS₂, CuInS, CuInS₂, InGaS₃, InGaSe₃, or the like, or an arbitrary combination thereof.

Examples of the Group I-III-VI semiconductor compound may include a three-element compound such as AgInS, AgInS₂, CuInS, CuInS₂, CuGaO₂, AgGaO₂, AgAlO₂, or the like, or an arbitrary combination thereof.

Examples of the IV-VI semiconductor compound may include a two-element compound such as SnS, SnSe, SnTe, PbS, PbSe, PbTe, or the like, a three-element compound such as SnSeS, SnSeTe, SnSTe, PbSeS, PbSeTe, PbSTe, SnPbS, SnPbSe, SnPbTe, or the like, a four-element compound such as SnPbSSe, SnPbSeTe, SnPbSTe, or the like, or an arbitrary combination thereof.

The Group IV element or compound may include a single-element compound such as Si, Ge, or the like, a two-element compound such as SiC, SiGe, or the like, or an arbitrary combination thereof.

Each of the elements included in a multi-element compound such as the two-element compound, the three-element compound, and the four-element compound may exist in particles in a uniform or non-uniform concentration.

The quantum dot may have a single structure, in which elements included in the quantum dot have a same concentration, or a dual structure of core-shell. For example, a material included in the core may be different from a material included in the shell. The shell of the quantum-dot may function as a protective layer for preventing chemical denaturation of the core and maintain the characteristics of the semiconductor and/or a charging layer for granting electrophoretic characteristics to the quantum dot. The shell may include a single layer or multiple layers. An interface between the core and the shell may have a concentration gradient in which a concentration of an element in the shell decreases toward a center.

Examples of the shell of the quantum dots may include an oxide of a metal or a non-metal, a semiconductor compound, or combinations thereof. Examples of the oxide of a metal or a non-metal may include a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or the like, a three-element compound such as MgAl₂O₄, CoFe₂O₄, NiFe₂O₄, CoMn₂O₄, or the like, or arbitrary combinations thereof. Examples of the semiconductor compound may include, as described above, the Group II-VI semiconductor compound, the Group III-VI compound, the Group I-III-Vi semiconductor compound, the Group IV-VI semiconductor compound, or arbitrary combinations thereof. For example, the semiconductor compound may include CdS, CdSe, CdTe, ZnS, ZnSe, ZnTe, ZnSeS, ZnTeS, GaAs, GaP, GaSb, HgS, HgSc, HgTe, InAs, InP, InGaP, InSb, AlAs, AlP, AlSb, or arbitrary combinations thereof.

The quantum dots may each have a full width of half maximum (FWHM) of an emission wavelength spectrum of about 45 nm or less, for example, about 40 nm or less, by way of example, about 30 nm or less, and color purity or color reproducibility may be improved in the aforementioned range. The light emitted through the quantum dots may be emitted in every direction, and therefore, a viewing angle of the light may be improved.

The form of the quantum dots may include the form of nanoparticles, nanotubes, nanowires, nanofibers, nano platelet particles having a spherical shape, a pyramid shape, a multi-arm shape, or a cubic shape.

As an energy band gap may be adjusted by adjusting sizes of the quantum dots, light of various wavelength bands may be obtained in emission layers of the quantum dots. Accordingly, by using quantum dots respectively having different sizes, emission devices that emit light of various wavelengths may be implemented. By way of example, the sizes of the quantum dots may be selected such that red light, green light, and/or blue light is emitted. The size of the quantum dots may be configured such that white light is emitted through a combination of light having different colors.

The blue light Lb may be transmitted through the transmitter 250c. The transmitter 250c may include a third photosensitive polymer 251c and third scattering particles 255c. The third scattering particles 255c may be distributed in the third photosensitive polymer 251c. The third photosensitive polymer 251c may include an organic material having light transmissivity, for example, a silicon resin, an epoxy resin, and the like, and may include a same material as a material of the first photosensitive polymer 251a and/or a material of the second photosensitive polymer 251b. The third scattering particles 255c may scatter and emit the blue light Lb, and may include a same material as a material of the first scattering particles 255a and/or the second scattering particles 255b.

The blue light Lb emitted from the emission panel 10 may be color-converted or transmitted through the first color-converter 250a, the second color-converter 250b, and the transmitter 250c, and the color purity of the blue light Lb may be improved while the blue light Lb passes through the color filter 240. For example, the blue light Lb emitted from the first display element DPE1 may be color-converted and filtered to be the red light Lr while passing through the first color-converter 250a and the first color filter 240a. The blue light Lb emitted from the second display element DPE2 may be color-converted and filtered to be the green light Lg while passing through the second color-converter 250b and the second color filter 240b. The blue light Lb emitted from the third display element DPE3 may be transmitted and filtered while passing through the transmitter 250c and the third color filter 240c.

The display device 1 having the aforementioned structure may be included in mobile phones, televisions, billboard charts, monitors, tablet PCs, notebooks, or the like within the spirit and the scope of the disclosure.

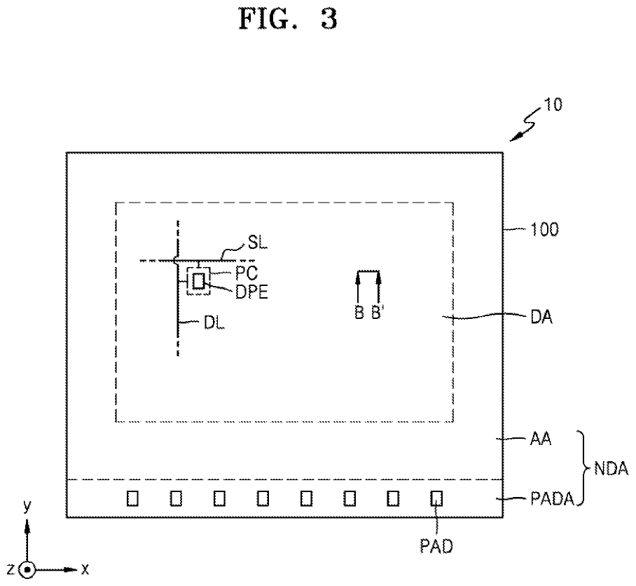

FIG. 3 is a schematic top-plan view schematically illustrating the emission panel 10 according to an embodiment.

Referring to FIG. 3, the emission panel 10 may include the substrate 100, a scan line SL, a data line DL, a pixel circuit PC, the display element DPE, and a pad. The display area DA and the non-display area NDA may be defined in the emission panel 10. According to an embodiment, the display area DA and the non-display area NDA may be defined in the substrate 100. In other words, the substrate 100 may include the display area DA and the non-display area NDA. Hereinafter, a case in which the substrate 100 may include the display area DA and the non-display area NDA will be described in detail.

The pixel circuit PC and the display element DPE may be disposed on the display area DA. According to an embodiment, pixel circuits PC and display elements DPE may be disposed on the display area DA. The display elements DPE may emit light.

The non-display area NDA may include an area in which the display elements DPE are not disposed. According to an embodiment, a driving circuit or a power voltage line to provide electric signals or power to the pixel circuit PC may be disposed on the non-display area NDA. The non-display area NDA may at least partially surround the display area DA. In an embodiment, the non-display area NDA may entirely surround the display area DA. The non-display area NDA may include an adjacent area AA and a pad area PADA. The adjacent area AA may include an area adjacent to the display area DA. The pad area PADA may be disposed outside the adjacent area AA. Although FIG. 3 illustrates that the pad area PADA is disposed outside the adjacent area AA in a −y direction, in an embodiment, the pad area PADA may also be disposed outside the adjacent area AA in the y direction, the −y direction, the x direction, and/or the −x direction.

The substrate 100 may include glass. According to an embodiment, the substrate 100 may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like within the spirit and the scope of the disclosure. According to an embodiment, the substrate 100 may include a multi-layer structure including a base layer including the aforementioned polymer resin and a barrier layer (not shown). Hereinafter, a case in which the substrate 100 may include glass will be described in detail.

The scan line SL may be electrically connected to the pixel circuit PC. In an embodiment, the scan line SL may extend in the x direction shown in FIG. 3. The data line DL may be electrically connected to the pixel circuit PC. In an embodiment, the data line DL may extend in the y direction shown in FIG. 3.

The pixel circuit PC may be electrically connected to the scan line SL to deliver a scan signal and the data line DL to drive the data signal. The pixel circuit PC may receive the scan signal and the data signal and drive the display element DPE.

The display element DPE may be disposed on the display area DA. The display element DPE may be driven by the pixel circuit PC. In an embodiment, the display element DPE may include an organic light-emitting diode including an organic emission layer. For example, the display element DPE may include an inorganic light-emitting diode including an inorganic emission layer. A size of the light-emitting diode may be in a range of microscale or nanoscale. For example, the light-emitting diode may include a micro light-emitting diode. For example, the light-emitting diode may include a nanorod light-emitting diode. The nanorod light-emitting diode may include gallium nitride (GaN). For example, the display element DPE may include a quantum-dot light-emitting diode including a quantum-dot emission layer.

The pad PAD may be disposed in the pad area PADA. In an embodiment, the pad PAD may be provided in plurality. The pad PAD may electrically connect components of the display device to the emission panel 10. For example, the emission panel 10 may be electrically connected to a driving chip and/or a printed circuit board through the pad PAD. The driving chip may include an integrated circuit (IC). The printed circuit board may include a flexible printed circuit board (FPCB) or a rigid printed circuit board (PCB) that is rigid and thus is not readily bent. For example, according to occasions, the printed circuit board may include a complex printed circuit board including both of the PCB and the FPCB. In an embodiment, a chip including an IC may be disposed on the printed circuit board.

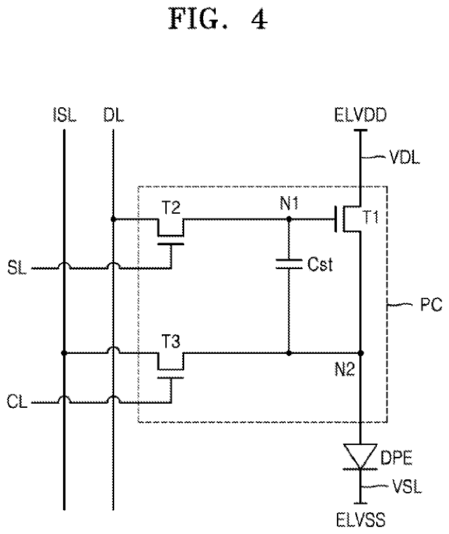

FIG. 4 is a schematic diagram of an equivalent circuit illustrating the pixel circuit PC and the display element DPE included in an emission panel according to an embodiment.

Referring to FIG. 4, the display element DPE may be electrically connected to the pixel circuit PC. In an embodiment, a pixel electrode of the display element DPE may be electrically connected to the pixel circuit PC, and a counter electrode of the display element DPE may be electrically connected to a common voltage line VSL to provide a common power voltage ELVSS. The display element DPE may emit light with a luminance corresponding to an amount of current provided from the pixel circuit PC.

The pixel circuit PC may control an amount of current flowing from a driving power voltage ELVDD to the common power voltage ELVSS via the display element DPE, in response to the data signal. The pixel circuit PC may include a first transistor T1, a second transistor T2, a third transistor T3, and a storage capacitor Cst.

Each of the first transistor T1, the second transistor T2, and the third transistor T3 may include an oxide semiconductor thin-film transistor, which may include a semiconductor layer including an oxide semiconductor, or a silicon semiconductor thin-film transistor including a semiconductor layer including polysilicon. According to types of the transistors, a first electrode may include any one of a source electrode and a drain electrode, and a second electrode may include another one of a source electrode and a drain electrode.

The first transistor T1 may include a driving transistor. A first electrode of the first transistor T1 may be electrically connected to a driving voltage line VDL to provide the driving power voltage ELVDD, and a second electrode of the first transistor T1 may be electrically connected to the pixel electrode of the display element DPE. A gate electrode of the first transistor T1 may be electrically connected to a first node N1. The first transistor T1 may control an amount of current flowing from the driving power voltage ELVDD through the display element DPE, in response to a voltage of the first node N1.

The second transistor T2 may include a switching transistor. A first electrode of the second transistor T2 may be electrically connected to the data line DL, and a second electrode of the second transistor T2 may be electrically connected to the first node N1. A gate electrode of the second transistor T2 may be electrically connected to the scan line SL. The second transistor T2 may be turned on in case that the scan signal is provided from the scan line SL and may electrically connect the data line DL and the first node N1.

The third transistor T3 may include an initialization transistor and/or a sensing transistor. A first electrode of the third transistor T3 may be electrically connected to a second node N2, and a second electrode of the third transistor T3 may be electrically connected to an initialization-sensing line ISL. A gate electrode of the third transistor T3 may be electrically connected to a control line CL.

The third transistor T3 may be turned on in case that a control signal is provided from the control line CL and may electrically connect the initialization-sensing line ISL and the second node N2. In an embodiment, the third transistor T3 may be turned on in response to a signal delivered through the control line and may initialize the pixel electrode of the display element DPE using an initialization voltage provided from the initialization-sensing line ISL. In an embodiment, the third transistor T3 may be turned on in case that the control signal is provided from the control line CL and may sense characteristic information of the display element DPE. The third transistor T3 may have all or any one of a function as the initialization transistor or a function of the sensing transistor. In an embodiment, in case that the third transistor T3 has the function as the initialization transistor, the initialization-sensing line ISL may be named as an initialization voltage line, and in case that the third transistor T3 has the function as the sensing transistor, the initialization-sensing line ISL may be named as a sensing line. An initialization operation and a sensing operation of the third transistor T3 may be separately performed or simultaneously performed. Hereinafter, for convenience of explanation, a case in which the third transistor T3 has both of the function of the initialization transistor and the function of the sensing transistor will be described in detail.

The storage capacitor Cst may be connected between the first node N1 and the second node N2. For example, one capacitor electrode of the storage capacitor Cst may be electrically connected to the pixel electrode of the display element DPE, and another one capacitor electrode of the storage capacitor Cst may be electrically connected to the gate electrode of the first transistor T1.

Although FIG. 4 illustrates the first transistor T1, the second transistor T2, and the third transistor T3 as NMOS, in other embodiments, at least one of the first transistor T1, the second transistor T2, and the third transistor T3 may be provided as PMOS.

Although FIG. 4 illustrates three transistors, in an embodiment, the pixel circuit PC may include four or more transistors. Although FIG. 4 illustrates one storage capacitor, in an embodiment, the pixel circuit PC may include two or more storage capacitors.

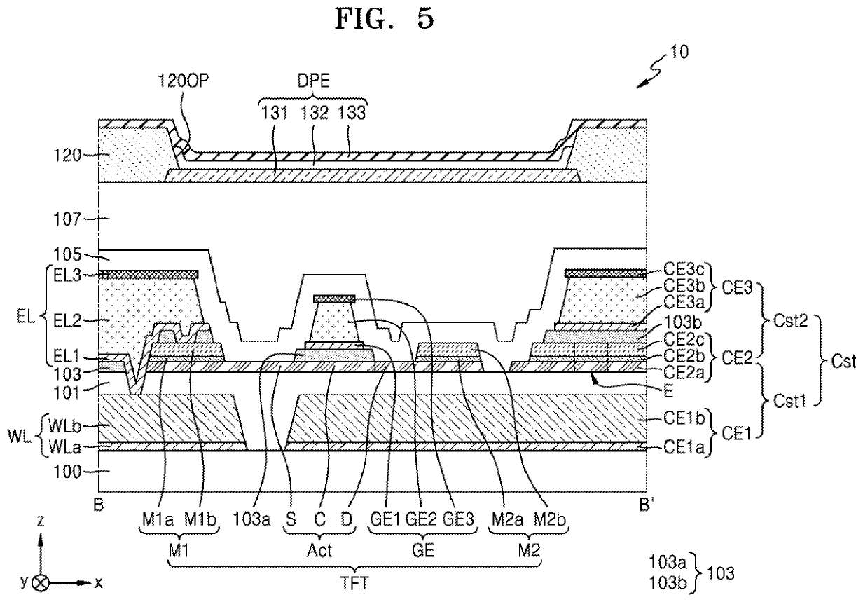

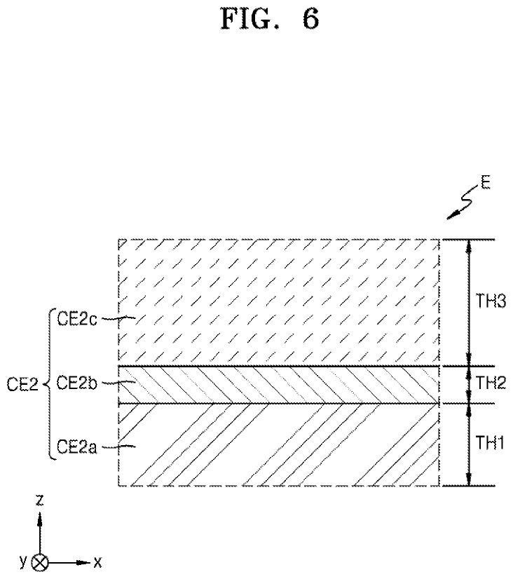

FIG. 5 is a schematic cross-sectional view schematically illustrating the emission panel 10 according to an embodiment, which is taken along line B-B′ in the display area DA of the emission panel 10 shown in FIG. 3. FIG. 6 is an enlarged schematic view illustrating an enlarged image of a second capacitor electrode of the area ‘E’ shown in FIG. 5, according to an embodiment.

Referring to FIGS. 5 and 6, the emission panel 10 may include the substrate 100, a pixel circuit layer, and a display element layer. In an embodiment, the substrate 100 may include glass.

The pixel circuit layer may be disposed on the substrate 100. The pixel circuit layer may include a wiring WL, a transistor TFT, the storage capacitor Cst, a buffer layer 101, a first inorganic insulating layer 103, a second inorganic insulating layer 105, and an organic insulating layer 107. The transistor TFT may include a semiconductor layer Act, a gate electrode GE, a first conductive layer M1, and a second conductive layer M2. In an embodiment, the storage capacitor Cst may include a first capacitor electrode CE1, a second capacitor electrode CE2, and a third capacitor electrode CE3. The first capacitor electrode CE1, the second capacitor electrode CE2, and the third capacitor electrode CE3 may overlap one another.

The wiring WL may be disposed on the substrate 100. The wiring may include a signal line and/or a voltage line. For example, the wiring WL may include the data line, the driving voltage line, the common voltage line, and/or the initialization-sensing line. The wiring WL may be disposed in the display area DA. The wiring WL may deliver a signal and/or a voltage to the transistor TFT.

The wiring WL and the first capacitor electrode CE1 may be disposed on a same layer. For example, the wiring WL and the first capacitor electrode CE1 may include a same material and may be formed in a same process. Hereinafter, the wiring WL will be described in detail.

The wiring WL may include a conductive material including molybdenum (Mo), aluminum (Al), copper (Cu), titanium (Ti), and the like, and may include multiple layers or a single layer including the aforementioned materials. In an embodiment, the wiring WL may include a first wiring layer WLa and a second wiring layer WLb. The second wiring layer WLb may be disposed on the first wiring layer WLa. The second wing layer WLb may include a highly conductive material. For example, the second wiring layer WLb may include copper (Cu). In an embodiment, the first wiring layer WLa may be omitted from the wiring WL. In an embodiment, the wiring WL may further include a third wiring layer.

In an embodiment, the first capacitor electrode CE1 may include a first layer CE1a of the first capacitor electrode CE1 and a second layer CE1b of the first capacitor electrode CE1. In an embodiment, the first layer CE1a of the first capacitor electrode CE1 and the first wiring layer WLa may include a same material. The second layer CE1b of the first capacitor electrode CE1 and the second wiring layer WLb may include a same material.

The buffer layer 101 may be disposed on the wiring WL and the first capacitor electrode CE1. The buffer layer 101 may include an opening exposing a portion of the wiring WL. The buffer layer 101 may include an inorganic insulating material such as silicon nitride (SiNₓ), silicon oxynitride (SiON), and silicon oxide (SiO₂), and may include a single layer or multiple layers including the aforementioned inorganic insulating materials.

The semiconductor layer Act may be disposed on the buffer layer 101. The semiconductor layer Act may include an oxide semiconductor. For example, the semiconductor layer Act may include an indium gallium zinc oxide (IGZO) semiconductor including metals such as indium (In), gallium (Ga), and tin (Sn) in addition to zinc oxide (ZnO), an indium tin zinc oxide (ITZO) semiconductor, or an indium gallium tin zinc oxide (IGTZO) semiconductor.

The semiconductor layer Act may include a source area S, a drain area D, and a channel area C disposed between the source area S and the drain area D. The source area S and the drain area D may have lower resistance than resistance of the channel area C. In an embodiment, impurities may be added to the source area S and the drain area D. For example, the source area S and the drain area D may include doped areas.

A first conductive layer M1 and a second conductive layer M2 may be disposed on the semiconductor layer Act. At least a portion of the first conductive layer M1 may overlap the source area S of the semiconductor layer Act. At least a portion of the second conductive layer M2 may overlap the drain area D of the semiconductor layer Act. The first conductive layer M1 may be disposed on the source area S of the semiconductor layer Act, and the second conductive layer M2 may be disposed on the drain area D of the semiconductor layer Act. The first conductive layer M1 and the second conductive layer M2 may contact the semiconductor layer Act. The first conductive layer M1 and the second conductive layer M2 may be not disposed on the channel area C of the semiconductor layer Act.

In an embodiment, the first conductive layer M1 may include a 1^{st}-1 conductive layer M1a and a 1^{st}-2 conductive layer M2a on the 1^{st}-1 conductive layer M1a. The second conductive layer M2 may include a 2^{nd}-1 conductive layer M2a and a 2^{nd}-2 conductive layer M2b on the 2^{nd}-1 conductive layer M2a. The 1^{st}-1 conductive layer M1a may be disposed between the 1^{st}-2 conductive layer M1b and the semiconductor layer Act. The 2^{nd}-1 conductive layer M2a may be disposed between the 2^{nd}-2 conductive layer M2b and the semiconductor layer Act.

The 1^{st}-1 conductive layer M1a and the 1^{st}-2 conductive layer M1b may be respectively disposed on an intermediate layer CE2b and an upper layer CE2c of the second capacitor electrode CE2 described below. The 2^{nd}-1 conductive layer M2a and the 2^{nd}-2 conductive layer M2b may be respectively disposed on the intermediate layer CE2b and an upper layer CE2c of the second capacitor electrode CE2 described below.

Although FIG. 5 illustrates that each of the first conductive layer M1 and the second conductive layer M2 may include two layers, the embodiments are not limited thereto. In other embodiments, the 1^{st}-1 conductive layer M1a and the 2^{nd}-1 conductive layer M2a may be omitted. For example, in case that the second capacitor electrode CE2 only may include a lower layer CE2a and the upper layer CE2c and does not include the intermediate layer CE2b, each of the first conductive layer M1 and the second conductive layer M2 may include a single layer including a same material as a material of the upper layer CE2c of the second capacitor electrode CE2.

The second capacitor electrode CE2 may be disposed on the buffer layer 101. The buffer layer 101 may be disposed between the first capacitor electrode CE1 and the second capacitor electrode CE2.

The second capacitor electrode CE2 may include an amorphous conductive oxide. Therefore, the second capacitor electrode CE2 may have a relatively low resistance. For example, the second capacitor electrode CE2 may have a resistance lower than a resistance of the channel area C of the semiconductor layer Act. The second capacitor electrode CE2 may function as an electrode plate of the storage capacitor Cst.

In an embodiment, the second capacitor electrode CE2 may include the lower layer CE2a, the intermediate layer CE2b, and the upper layer CE2c. The lower layer CE2a, the intermediate layer CE2b, and the upper layer CE2c of the second capacitor electrode CE2 may respectively include different conductive oxides. The different conductive oxides may include conductive oxides having different composition ratios among conductive oxides including same atoms.

The lower layer CE2a of the second capacitor electrode CE2 may be disposed on the buffer layer 101. The lower layer CE2a of the second capacitor electrode CE2 may be disposed on a same layer as the semiconductor layer Act of the transistor TFT.

The lower layer CE2a of the second capacitor electrode CE2 may include an amorphous conductive oxide. The upper electrode CE2a of the second capacitor electrode CE2 may include, for example, an indium gallium zinc oxide (IGZO) including metals such as In, Ga, and Sn in addition to ZnO, an ITZO semiconductor, or an IGTZO semiconductor. In an embodiment, in case that the lower layer CE2a of the second capacitor electrode CE2 may include IGZO, the IGZO may include zinc (Zn) of about 11 at % or more but not more than about 16 at %, In of about 10 at % or more but not more than about 15 at %, Ga of more than about 10 at % but not more than about 20 at %, and oxygen (O) of about 58 at % or more but not more than about 62 at %.

The upper layer CE2c of the second capacitor electrode CE2 may be disposed on the lower layer CE2a of the second capacitor electrode CE2. In an embodiment, the upper layer CE2c of the second capacitor electrode CE2 may be disposed on the intermediate layer CE2b of the second capacitor electrode CE2. The upper layer CE2c of the second capacitor electrode CE2 may be disposed on a same layer as the 1^{st}-2 conductive layer M1b and the 2^{nd}-2 conductive layer M2b. The upper layer CE2c of the second capacitor electrode CE2 may be formed in a same process as a process in which the 1^{st}-2 conductive layer M1b and the 2^{nd}-2 conductive layer M2b are formed, and may include a same material as a material of the 1^{st}-2 conductive layer M1b and the 2^{nd}-2 conductive layer M2b.

The upper layer CE2c of the second capacitor electrode CE2 may include an amorphous conductive oxide. For example, the upper layer CE2c of the second capacitor electrode CE2 may include at least one of zinc indium oxide (ZIO), hafnium oxide (HfOₓ), aluminum oxide (AlₓO_{y}), zirconium oxide (ZrOₓ), zirconium aluminum oxide (Zr—Al₂O₃), hafnium lanthan oxide (HfLaO), titanium oxide (TiO₂), zinc aluminum oxide (ZAO), p-silicon oxide (p-SiOₓ), zinc oxide (ZnO), indium oxide (In₂O₃), gallium oxide (Ga₂O₃), indium oxynitride (InON), indium tin oxide (ITO), indium zinc oxide (IZO), indium gallium oxide (IGO), ITGO, IGZO, ITGZO, or aluminum indium zinc oxide (AlZO).

In an embodiment, in case that the upper layer CE2c of the second capacitor electrode CE2 may include ZIO, the ZIO may include Zn of about 12 at % or more but not more than about 16 at %, In of about 13 at % or more but not more than about 23 at %, and O of about 58 at % or more but not more than about 65 at %. In case that the aforementioned composition range is satisfied, IZO may be amorphous. In case that the aforementioned composition ratio is not satisfied, at least a portion of ZIO may be crystalline, as in the Comparative Example 1 and the Comparative Example 2 described with reference to table 1 below.

As the upper layer CE2c of the second capacitor electrode CE2 may include an amorphous conductive oxide, the second capacitor electrode CE2 may have a low resistance. For example, a sheet resistance of the second capacitor electrode CE2 may be about 300 (2 or less. As the second capacitor electrode CE2 has the low resistance, the performance of the storage capacitor Cst may be improved.

The upper layer CE2c of the second capacitor electrode CE2 may be formed through a sputtering process, atomic layer deposition (ALD) layer, PECVD process, SOL-GEL process, or the like within the spirit and the scope of the disclosure.

In an embodiment, the intermediate layer CE2b of the second capacitor electrode CE2 may be disposed between the lower layer CE2a of the second capacitor electrode CE2 and the upper layer CE2c of the second capacitor electrode CE2. In an embodiment, the intermediate layer CE2b of the second capacitor electrode CE2 may be disposed in an entire area between the lower layer CE2a of the second capacitor electrode CE2 and the upper layer CE2c of the second capacitor electrode CE2, as shown in FIGS. 5 and 6.

As the second capacitor electrode CE2 further may include the intermediate layer CE2b disposed between the lower layer CE2a and the upper layer CE2c, damage to the lower layer CE2a may be prevented. Accordingly, the reliability of the display device may be improved.

The intermediate layer CE2b of the second capacitor electrode CE2 may be disposed on a same layer as the 1^{st}-1 conductive layer M1a and the 2^{nd}-1 conductive layer M2a. The intermediate layer CE2b of the second capacitor electrode CE2 may be formed in a same process as a process in which the 1^{st}-1 conductive layer M1a and the 2^{nd}-1 conductive layer M2a are formed, and may include a same material as a material of the 1^{st}-1 conductive layer M1a and the 2^{nd}-1 conductive layer M2a.

The intermediate layer CE2b of the second capacitor electrode CE2 may include an intermixing layer in which the lower layer CE2a of the second capacitor electrode CE2 and the upper layer CE2c of the second capacitor electrode CE2 are mixed each other. Accordingly, the intermediate layer CE2b of the second capacitor electrode CE2 may include a conductive oxide formed by mixing a material of the lower layer CE2a of the second capacitor electrode CE2 and a material of the upper electrode CE2c of the second capacitor electrode CE2. In other words, the intermediate layer CE2b of the second capacitor electrode CE2 may include a conductive oxide including atoms included in the lower layer CE2a of the second capacitor electrode CE2 and atoms included in the upper layer CE2c of the second capacitor electrode CE2.

The intermediate layer CE2b of the second capacitor electrode CE2 may include an amorphous conductive oxide. For example, the intermediate layer CE2b of the second capacitor electrode CE2 may include an amorphous conductive oxide including In of about 10 at % or more but not more than about 30 at %. In case that the lower layer CE2a and/or the upper layer CE2c of the second capacitor electrode CE2 may include Ga, the intermediate layer CE2b of the second capacitor electrode CE2 may include an amorphous conductive oxide including In of about 10 at % or more but not more than about 30 at % and Ga of more than about 0 at % but not more than about 20 at %.

In an embodiment, in case that the lower layer CE2a of the second capacitor electrode CE2 may include IGZO and the upper layer CE2c of the second capacitor electrode CE2 may include IZO, the intermediate layer CE2b of the second capacitor electrode CE2 may include IGZO. IGZO in the lower layer CE2a and IGZO in the intermediate layer CE2b may have different composition ratios.

The intermediate layer CE2b of the second capacitor electrode CE2, in which the lower layer CE2a and the upper layer CE2c are combined to each other, may have a small thickness. For example, TH2 of the intermediate layer CE2b of the second capacitor electrode CE2 may have a range of about 5 Å or more but not more than about 50 Å.

As shown in FIG. 6, the thickness TH2 of the intermediate layer CE2b of the second capacitor electrode CE2 may be less than a thickness TH1 of the lower layer CE2a of the second capacitor electrode CE2 and a thickness TH3 of the upper layer CE2c of the second capacitor electrode CE2. In an embodiment, the thickness TH1 of the lower layer CE2a of the second capacitor electrode CE2 may be less than the thickness TH3 of the upper layer CE2c of the second capacitor electrode CE2. The thickness TH1 of the lower layer CE2a of the second capacitor electrode CE2 may be, for example, about 250 Å or more but not more than about 350 Å. The thickness TH3 of the upper layer CE2c of the second capacitor electrode CE2 may be, for example, about 450 Å or more but not more than about 550 Å.

The first inorganic insulating layer 103 may be disposed on the first conductive layer M1, the second conductive layer M2, the semiconductor layer Act, and the second capacitor electrode CE2. The first inorganic insulating layer 103 may include holes. For example, the first inorganic insulating layer 103 may include a first contact hole exposing a portion of the first conductive layer M1. Through the first contact hole, the first conductive layer M1 may be electrically connected to a first electrode layer EL1 to be described later. For example, the first inorganic insulating layer 103 may include holes exposing at least a portion of the semiconductor layer Act.

The first inorganic insulating layer 103 may include a first insulating pattern 103a disposed between the semiconductor layer Act and the gate electrode GE. The first insulating pattern 103a may be disposed to overlap the channel area C of the semiconductor layer Act and the gate electrode GE. The first insulating pattern 103a may be disposed right on the semiconductor layer Act.

The first inorganic insulating layer 103 may include a second insulating pattern 103b disposed between the second capacitor electrode CE2 and the third capacitor electrode CE3. The second insulating pattern 103b may be disposed right on the upper layer CE2c of the second capacitor electrode CE2.

The first electrode EL may be disposed on the first inorganic insulating layer 103. At least a portion of the first electrode EL may overlap the semiconductor layer Act and the first conductive layer M1. The first electrode EL may be electrically connected to the first conductive layer M1 through the first contact hole in the first inorganic insulating layer 103. The first electrode EL may be electrically connected to the wiring WL through a contact hole in the buffer layer 101. Accordingly, the transistor TFT may receive signals and/or voltages from the wiring WL. Although FIG. 5 illustrates that an electrode is not disposed in an area overlapping the second conductive layer M2 in the z direction, the embodiments are not limited thereto, and in other embodiments, a second electrode electrically connected to the second conductive layer M2 may be disposed on the second conductive layer M2.

The first electrode EL may include a conductive material including molybdenum (Mo), aluminum (Al), copper (Cu), titanium (Ti), and the like, and may include multiple layers or a single layer including the aforementioned materials. In an embodiment, the first electrode EL may include a transparent conductive material. For example, the first electrode EL may include a conductive oxide such as indium tin oxide (ITO), indium zinc oxide (IZO), zinc oxide (ZnO), indium oxide (In₂O₃), indium gallium oxide (IGO), or aluminum zinc oxide (AZO).

In an embodiment, the first electrode EL may include a first electrode layer EL1, a second electrode layer EL2, and a third electrode layer EL3. The first electrode layer EL1 may include, for example, Ti. The second electrode layer EL2 may be disposed on the first electrode layer EL1. The second electrode layer EL2 may include, for example, Cu. The third electrode layer EL3 may be disposed on the second electrode layer EL2. The third electrode layer EL3 may include, for example, ITO. The third electrode layer EL3 may prevent or reduce damage to the second electrode layer EL2 during a process of manufacturing the display device. In an embodiment, in case that the second electrode layer EL2 has chemical resistance, the third electrode layer EL3 may be omitted.

The first electrode EL, the gate electrode GE, and the third capacitor electrode CE3 may be disposed on a same layer. In other words, each of the first electrode EL, the gate electrode GE, and the third capacitor electrode CE3 may be disposed between the first inorganic insulating layer 103 and the second inorganic insulating layer 105. The first electrode EL, the gate electrode GE, and the third capacitor electrode CE3 may include a same material and may be formed through a same process.

The gate electrode GE may be disposed on the first insulating pattern 103a. The gate electrode GE may be disposed to overlap the channel area C of the semiconductor layer Act. In an embodiment, the gate electrode GE may be disposed apart from each of the first conductive layer M1 and the second conductive layer M2. In an embodiment, the gate electrode GE may be disposed between the first conductive layer M1 and the second conductive layer M2.

In an embodiment, similarly to the first electrode EL, the gate electrode GE may include a first gate electrode layer GE1, a second gate electrode layer GE2, and a third gate electrode layer GE3. The first gate electrode layer GE1, the second gate electrode layer GE2, and the third gate electrode layer GE3 may include same materials as the materials of the first electrode layer EL1, the second electrode layer EL2, and the third electrode layer EL3. In an embodiment, in case that the second gate electrode layer GE2 has chemical resistance, the third gate electrode layer GE3 may be omitted.

The third capacitor electrode CE3 may be disposed to overlap the second capacitor electrode CE2. The third capacitor electrode CE3 may be disposed on the second insulating pattern 103b. In an embodiment, similarly to the first electrode EL, the third capacitor electrode CE3 may include a first layer CE3a, a second layer CE3b, and a third layer CE3c. The first layer CE3a, the second layer CE3b, and the third layer CE3c of the third capacitor electrode CE3 may include same materials as the materials of the first electrode layer EL1, the second electrode layer EL2, and the third electrode layer EL3. In an embodiment, the third layer CE3c of the third capacitor electrode CE3 may be omitted.

The storage capacitor Cst may include the first capacitor electrode CE1, the second capacitor electrode CE2, and the third capacitor electrode CE3. In an embodiment, the storage capacitor Cst may include a first storage capacitor including the first capacitor electrode CE1 and the second capacitor electrode CE2 and a second storage capacitor including the second capacitor electrode CE2 and the third capacitor electrode CE3. In the embodiment, each layer in the second capacitor electrode CE2 may include an amorphous conductive oxide. Therefore, the second capacitor electrode CE2 may function as an electrode plate, and the storage capacitor Cst may have an increased capacity as a dual-storage capacitor. As each layer of the second capacitor electrode CE2 may include an amorphous conductive oxide, the degradation in characteristics of devices may be prevented.

The second inorganic insulating layer 105 may be disposed on the first electrode EL, the gate electrode GE, and the storage capacitor Cst. The second inorganic insulating layer 105 may be disposed on the first conductive layer M1 and the second conductive layer M2. In an embodiment, the second inorganic insulating layer 105 may cover the first electrode EL, the gate electrode GE, and the storage capacitor Cst. In an embodiment, the second inorganic insulating layer 105 may continuously extend.

The second inorganic insulating layer 105 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium (HfO₂), and/or zinc oxide (ZnOₓ). In an embodiment, the zinc oxide (ZnO) may include ZnO or zinc peroxide (ZnO₂).

The organic insulating layer 107 may be disposed on the second inorganic insulating layer 105. The organic insulating layer 107 may include an organic material. The organic insulating layer 107 may include an organic insulating material, for example, a general-purpose polymer such as polymethylmethacrylate (PMMA) or polystyrene (PS), a polymer derivative having a phenol-based group, an acryl-based polymer, an imide-based polymer, an arylether-based polymer, an amide-based polymer, a fluoride-based polymer, a p-xylene-based polymer, a vinylalcohol-based polymer, and blends thereof.

The display element layer may be disposed on the pixel circuit layer. The display element layer may include the display element DPE and a pixel defining layer 120. The display element DPE may include a pixel electrode 131, an emission layer 132, and a counter electrode 133. In an embodiment, the display element DPE may be disposed on the organic insulating layer 107.

The pixel electrode 131 may be disposed on the organic insulating layer 107. The pixel electrode 131 may be electrically connected to the transistor TFT.

The pixel electrode 131 may include a conductive oxide such as ITO, IZO, ZnO, In₂O₃, IGO, or AZO. In an embodiment, the pixel electrode 131 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In an embodiment, the pixel electrode 131 may further include a film including ITO, IZO, ZnO, or In₂O₃ below or above the reflective film.

The pixel defining layer 120 having an opening 120OP exposing a center portion of the pixel electrode 131 may be disposed on the pixel electrode 131. The pixel defining layer 120 may be disposed on the organic insulating layer 107 and cover an edge of the pixel electrode 131. In an embodiment, the opening 120OP of the pixel defining layer 120 may define an emission area of light emitted from the display element DPE. For example, a width of the opening 120OP of the pixel defining layer 120 may correspond to a width of the emission area.

In an embodiment, the pixel defining layer 120 may include an organic insulating material. In an embodiment, the pixel defining layer 120 may include an inorganic insulating material such as SiNₓ, SiON, or SiO₂. In an embodiment, the pixel defining layer 120 may include an organic insulating material and an inorganic insulating material. In an embodiment, the pixel defining layer 120 may include a light-shielding material and may be provided in black color. The light-shielding material may include a resin or paste including carbon black, carbon nanotube, or a black dye, metal particles such as nickel, aluminum, molybdenum, alloys thereof, metal oxide particles (for example, chromium oxide), metal nitride particles (for example, chromium nitride), or the like within the spirit and the scope of the disclosure. In case that the pixel defining layer 120 may include the light-shielding material, reflection of external light due to metal structures disposed below the pixel defining layer 120 may be reduced.

The emission layer 132 may be disposed in the opening 120OP of the pixel defining layer 120. The emission layer 132 may include a high-molecular organic material or a low-molecular organic material emitting light having given colors. Although not shown, a first function layer and a second function layer may be respectively disposed below and on the emission layer 132. The first function layer may include, for example, a hole transport layer (HTL) or an HTL and a hole injection layer (HIL). The second function layer is an optional component disposed on the emission layer 132. The second function layer may include an electron transport layer (EIL) and/or an electron injection layer (EIL).

The counter electrode 133 may be disposed on the emission layer 132. In an embodiment, the counter electrode 133 may continuously extend in the display area DA. The counter electrode 133 may include a conductive material having a small work function. For example, the counter electrode 133 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or alloys thereof. For example, the counter electrode 133 may further include a layer including a material such as ITO, IZO, ZnO, or In₂O₃ on the (semi) transparent layer including the aforementioned materials.

The display element DPE may be covered with an encapsulation layer including at least one organic encapsulation layer and at least one inorganic encapsulation layer. In an embodiment, the at least one inorganic encapsulation layer and the at least one organic encapsulation layer may be alternately stacked each other. The inorganic encapsulation layer may include one or more inorganic materials from among aluminum oxide (Al₂O₃), titanium oxide (TiO₂), tantalum oxide (Ta₂O₅), zinc oxide (ZnO), silicon oxide (SiO₂), silicon nitride (SiNₓ), and silicon oxynitride (SiON). The organic encapsulation layer may include a polymer-based material. The polymer-based material may include an acryl-based resin, an epoxy-based resin, polyimide, polyethylene, or the like within the spirit and the scope of the disclosure. In an embodiment, the organic encapsulation may include acrylate.

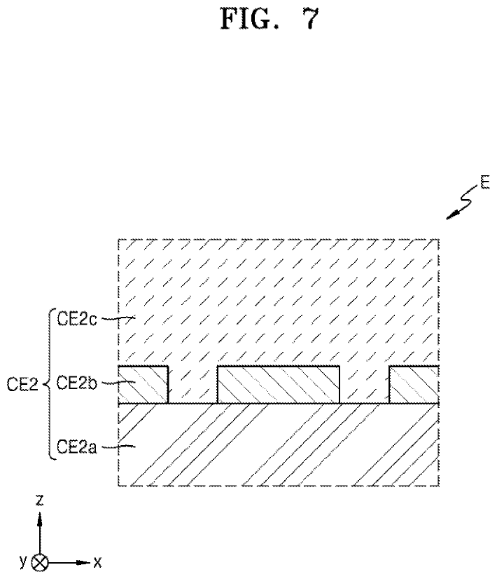

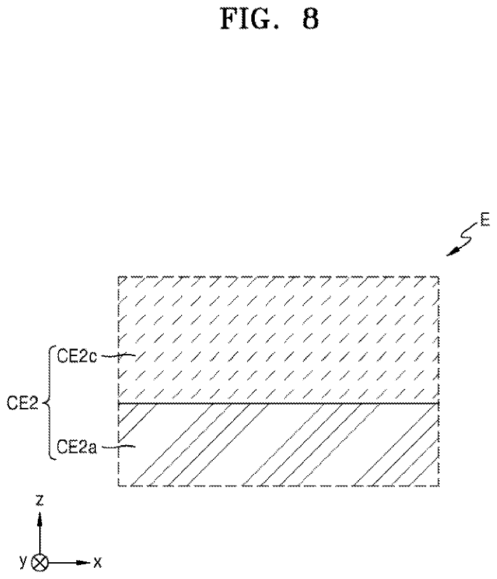

FIG. 7 is an enlarged view illustrating an enlarged image of the second capacitor electrode CE2 of the area ‘E’ shown in FIG. 5, according to an embodiment. FIG. 8 is an enlarged view illustrating an enlarged image of the second capacitor electrode CE2 of the area ‘E’ shown in FIG. 5, according to an embodiment. FIGS. 7 and 8 are each an enlarged view of the second capacitor electrode CE2 according to a modified embodiment of the embodiment described with reference to FIGS. 5 and 6. Accordingly, same descriptions with descriptions with reference to FIGS. 5 and 6 will be omitted, and modifications will be described.

Referring to FIG. 7, the intermediate layer CE2b of the second capacitor electrode CE2 may be disposed in an area between the lower layer CE2a of the second capacitor electrode CE2 and the upper layer CE2c of the second capacitor electrode CE2. For example, in an area of the second capacitor electrode CE2, the intermediate layer CE2b may be disposed between the lower layer CE2a and the upper layer CE2c, and in another area of the second capacitor electrode CE2, the upper layer CE2c may be disposed right on the lower layer CE2a. As shown in FIG. 7, the intermediate layer CE2b of the second capacitor electrode CE2 may have the form of including patterns. In an embodiment, the patterns included in the intermediate layer CE2b of the second capacitor electrode CE2 may be irregularly arranged or disposed, but the embodiment is not limited thereto.

Referring to FIG. 8, the second capacitor electrode CE2 may not include the intermediate layer CE2b. For example, the second capacitor electrode CE2 may have a double-layer structure including the lower layer CE2a and the upper layer CE2c. The first conductive layer M1 and the second conductive layer M2 described above with reference to FIG. 5 may each include a single layer including a same material as a material of the upper layer CE2c. In an embodiment, the upper layer CE2c may be disposed right on the lower layer CE2a of the second capacitor electrode CE2.

As the embodiments include the upper layer CE2c of the second capacitor electrode CE2 including an amorphous conductive oxide, degradation in characteristics of the second capacitor electrode CE2 may be prevented, and resistance may be reduced, therefore, the performance of the storage capacitor Cst may be improved.

TABLE 1

| | | Comparative | Comparative | |
|---|---|---|---|---|
| | | Example 1 | Example 2 | Embodiment |
| upper layer | composition | O:Zn:Ga:In = | O:Zn:Ga:In = | O:Zn:Ga:In = |
| | (at %) | 55:41:0:3 | 59:32:0:9 | 61:16:0:23 |
| | structure | crystalline | crystalline | amorphous |
| lower layer | composition | O:Zn:Ga:In = | O:Zn:Ga:In = | O:Zn:Ga:In = |
| | (at %) | 62:11:14:13 | 63:11:14:12 | 60:12:15:13 |
| | structure | amorphous | amorphous | amorphous |
| intermediate | composition | — | O:Zn:Ga:In = | O:Zn:Ga:In = |
| layer | (at %) | | 59:32:0:9 | 61:13:8:18 |
| | structure | — | amorphous | amorphous |

| | | | |
|---|---|---|---|
| Rs((Ω) | 37468 | 18230 | 238.4 |

Table 1 shows Comparative Examples and embodiments in which the second capacitor electrode CE2 described with reference to FIGS. 5 and 6 may include the lower layer CE2a including IGZO and the upper layer CE2c including IZO.

Comparative Example 1 in Table 1 shows a composition and a structure of the upper layer formed in case that a composition ratio of Zn and In included in the upper layer is 9:1 in a process of forming the upper layer of the second capacitor electrode. The lower layer in the Comparative Example 1 may include amorphous IGZO having a composition ratio of O:Zn:Ga:In=62:11:14:13.

Comparative Example 2 in Table 1 shows compositions and structures of the intermediate layer and the upper layer formed in case that a composition ratio of Zn:In is 7:3 in the process of forming the upper layer of the second capacitor electrode. The lower layer in the Comparative Example 2 may include amorphous IGZO having a composition ratio of O:Zn:Ga:In=63:11:14:12.

The embodiment in Table 1 shows compositions and structures of the intermediate layer and the upper layer formed in case that a composition ratio of Zn:In is 3:7 in the process of forming the upper layer of the second capacitor electrode. The lower layer in the embodiment in Table 1 may include amorphous IGZO having a composition ratio of O:Zn:Ga:In=60:12:15:13.

Referring to FIG. 1, it is seen that the second capacitor electrode in the Comparative Example 1 does not include an intermediate layer and may include an upper layer including crystalline IZO. IZO in the upper layer formed may include O of about 55 at %, Zn of about 41 at %, and In of about 3 at %. The second capacitor electrode in the Comparative Example 1 has a sheet resistance value of about 37.5 kΩ.

It is seen that the second capacitor electrode in the Comparative Example 2 may include the upper layer including crystalline IZO and the intermediate layer including amorphous IZO. IZO in each of the upper layer and the intermediate layer formed may include O of about 59 at %, Zn of about 32 at %, and In of about 9 at %. The second capacitor electrode in the Comparative Example 2 has a sheet resistance value of about 18.2 kΩ.

It is seen that the second capacitor electrode of the embodiment in Table 1 may include the upper layer including amorphous IZO and the intermediate layer including amorphous IGZO. IZO in the upper layer formed may include O of about 61 at %, Zn of about 16 at %, and In of about 23 at %, and IGZO in the intermediate layer may include O of about 61 at %, Zn of about 13 at %, Ga of about 8 at %, and In of about 18 at %. The second capacitor electrode in the embodiment in Table 1 has a sheet resistance value of about 238.4 (2. Accordingly, it is seen that the embodiment in Table 1 has a sheet resistance value that has been significantly reduced compared with cases in which the second capacitor electrode CE2 may include the upper layer that is crystalline as the Comparative Examples 1 and 2.

It is seen that, in case that Zn is included in a greater amount than an amount of In as in the Comparative Examples 1 and 2 in the process of forming the upper layer, at least some of IZO in the upper layer is crystalline. On the other hand, it is seen that, in case that Zn is included in a less amount than the amount of In in the process of forming the upper layer, as in the embodiment in Table 1, IZO in the upper layer is amorphous. For example, it is seen that, in case that a ratio of Zn in the process of forming the upper layer is equal to or less than a ratio of In, amorphous IZO is formed.

In the process of forming the upper layer, in case that Zn is included relatively less than In, the amorphous ZIO that is formed may include O of about 12 at % or more but not more than about 16 at %, In of about 13 at % or more but not more than about 23 at %, and O of about 58 at % or more but not more than about 65 at %. It is seen that the upper layer formed in the Comparative Examples 1 and 2 do not satisfy a composition ratio of the aforementioned ZIO, and the upper layer including IZO satisfying the aforementioned composition ratio is formed in the embodiment.

In case that the amorphous upper layer is formed as in the embodiment in Table 1, IZO in the upper layer and amorphous IGZO in the lower layer are mixed, and thus the intermediate layer including IZO having a composition ratio different from a composition ratio of the IGZO in the lower layer is formed. In case that forming the intermediate layer between the upper layer and the lower layer in the second capacitor electrode, damage to the lower layer according to an etching process may be prevented, and thus, the reliability of the storage capacitor may be improved.

According to the embodiments, the display device in which a capacity of the capacitor is secured may be provided. The display device with improved reliability may be provided.

Advantageous effects of the embodiments are not limited to the effects described above, and other effects not described above may be clearly understood to those skilled in the art from the descriptions in the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A display device comprising:
a transistor including a semiconductor layer and a gate electrode overlapping a channel area of the semiconductor layer; and
a storage capacitor electrically connected to the transistor, the storage capacitor comprising:
a first capacitor electrode disposed below the semiconductor layer;
a second capacitor electrode disposed on the first capacitor electrode; and
a third capacitor electrode disposed on the second capacitor electrode, wherein
the second capacitor electrode comprises:
a lower layer, the lower layer and the semiconductor layer being disposed on a same layer;
an intermediate layer disposed on the lower layer; and
an upper layer disposed on the intermediate layer, and
the upper layer of the second capacitor electrode comprises an amorphous conductive oxide.

2. The display device of claim 1, further comprising:
a buffer layer disposed between the first capacitor electrode and the second capacitor electrode; and
an inorganic insulating layer comprising a first insulating pattern disposed between the semiconductor layer and the gate electrode and a second insulating pattern disposed between the second capacitor electrode and the third capacitor electrode,
wherein the first insulating pattern is disposed directly on the semiconductor layer and the second insulating pattern is disposed directly on the upper layer of the second capacitor electrode.

3. The display device of claim 1, wherein a thickness of the intermediate layer is less than a thickness of the lower layer and a thickness of the upper layer of the second capacitor electrode.

4. The display device of claim 3, wherein the thickness of the lower layer is less than the thickness of the upper layer of the second capacitor electrode.

5. The display device of claim 3, wherein the thickness of the intermediate layer of the second capacitor electrode is about 5 Å or more but not more than about 50 Å.

6. The display device of claim 1, wherein each of the lower layer and the intermediate layer comprises an amorphous conductive oxide.

7. The display device of claim 1, wherein
the upper layer comprises amorphous zinc indium oxide (ZIO), and
the ZIO comprises:
zinc of about 12 at % or more but not more than about 16 at %;
indium of about 13 at % or more but not more than about 23 at %; and
oxygen of about 58 at % or more but not more than about 65 at %.

8. The display device of claim 1, wherein the intermediate layer comprises indium of about 10 at % or more but not more than about 30 at %.

9. The display device of claim 8, wherein the intermediate layer further comprises gallium of more than about 0 at % but not more than about 20 at %.

10. The display device of claim 1, wherein the lower layer comprises amorphous indium-gallium zinc oxide (IGZO).

11. The display device of claim 1, wherein the intermediate layer is disposed in an entire area between the lower layer and the upper layer of the second capacitor electrode.

12. The display device of claim 1, wherein the intermediate layer is disposed in a partial area between the lower layer and the upper layer of the second capacitor electrode.

13. The display device of claim 1, further comprising:
a wiring, the wiring and the first capacitor electrode being disposed on a same layer, and
a conductive layer disposed on the semiconductor layer; and
the conductive layer is electrically connected to the wiring.

14. The display device of claim 13, wherein the conductive layer comprises:
a first conductive layer, the first conductive layer and the intermediate layer of the second capacitor electrode being disposed on a same layer; and
a second conductive layer disposed on the first conductive layer, the second conductive layer and the upper layer of the second capacitor electrode being disposed on a same layer.

15. A display device comprising:
a transistor including a semiconductor layer and a gate electrode overlapping a channel area of the semiconductor layer; and
a storage capacitor electrically connected to the transistor and comprising:
a first capacitor electrode disposed below the semiconductor layer;
a second capacitor electrode disposed on the first capacitor electrode; and
a third capacitor electrode disposed on the second capacitor electrode, wherein
the second capacitor comprises:
a lower layer, the lower layer and the semiconductor layer being disposed on a same layer; and
an upper layer disposed on the lower layer, and
each of the lower layer and the upper layer of the second capacitor electrode comprises an amorphous conductive oxide.

16. The display device of claim 15, wherein the upper layer comprises amorphous zinc indium oxide (ZIO).

17. The display device of claim 16, wherein the ZIO comprises:
zinc of about 12 at % or more but not more than about 16 at %;
indium of about 13 at % or more but not more than about 23 at %; and
oxygen of about 58 at % or more but not more than about 65 at %.

18. The display device of claim 15, wherein
the second capacitor electrode further comprises an intermediate layer disposed between the lower layer and the upper layer of the second capacitor electrode, and
the intermediate layer comprises an amorphous conductive oxide including atoms included in the lower layer and atoms included in the upper layer of the second capacitor electrode.

19. The display device of claim 18, wherein a thickness of the intermediate layer is less than a thickness of the upper layer and a thickness of the lower layer of the second capacitor electrode.

20. The display device of claim 15, further comprising:
a wiring, the wiring and the first capacitor electrode being disposed on a same layer; and
a conductive layer disposed on the semiconductor layer,
wherein the conductive layer is electrically connected to the wiring, and
the conductive layer and the upper layer of the second capacitor electrode are disposed on a same layer.
